(19) United States
(12) Patent Application Publication
(10) Pub. No.: US 2013/0322027 A1
(43) Pub. Date: Dec. 5, 2013

(54) ELECTRONIC DEVICE AND MEMORY ASSEMBLY

(71) Applicant: Feng-Chi YANG, Tu-Cheng (TW)

(72) Inventor: Feng-Chi YANG, Tu-Cheng (TW)

(73) Assignee: HON HAI PRECISION INDUSTRY CO., LTD., Tu-Cheng (TW)

(21) Appl. No.: 13/531,410

(22) Filed: Jun. 22, 2012

(30) Foreign Application Priority Data
May 31, 2012 (CN) 201210176195.6

(51) Int. Cl. H05K 1/14

(52) U.S. Cl. 361/736

(57) ABSTRACT

An electronic device includes a chassis, a first printed circuit board (PCB), a second PCB, a third PCB, and a number of memory modules. Each memory module includes two edge connectors respectively formed on two opposite sides of the memory module. A plurality of parallel sockets is formed on each of the first and second PCBs.

The edge connectors are respectively inserted into the sockets of the first PCB and the sockets of the second PCB. The third PCB is electrically connected between the first PCB and the second PCB.

### BACKGROUND

1. Technical Field

The present disclosure relates to electronic devices, and particularly to an electronic device with a memory assembly.

2. Description of Related Art

Memory modules are used for electronic devices, such as computers or servers, to store data. A reduction in the size of electronic devices coupled with an increase in high speed, large capacity memory modules are required. Accordingly, a number of memory modules can be installed on a motherboard of the electronic device. However, the memory modules may occupy a large amount of area of the motherboard.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of an electronic device, wherein the electronic includes a memory assembly.

FIG. 2 is an exploded, isometric view of the memory assembly of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

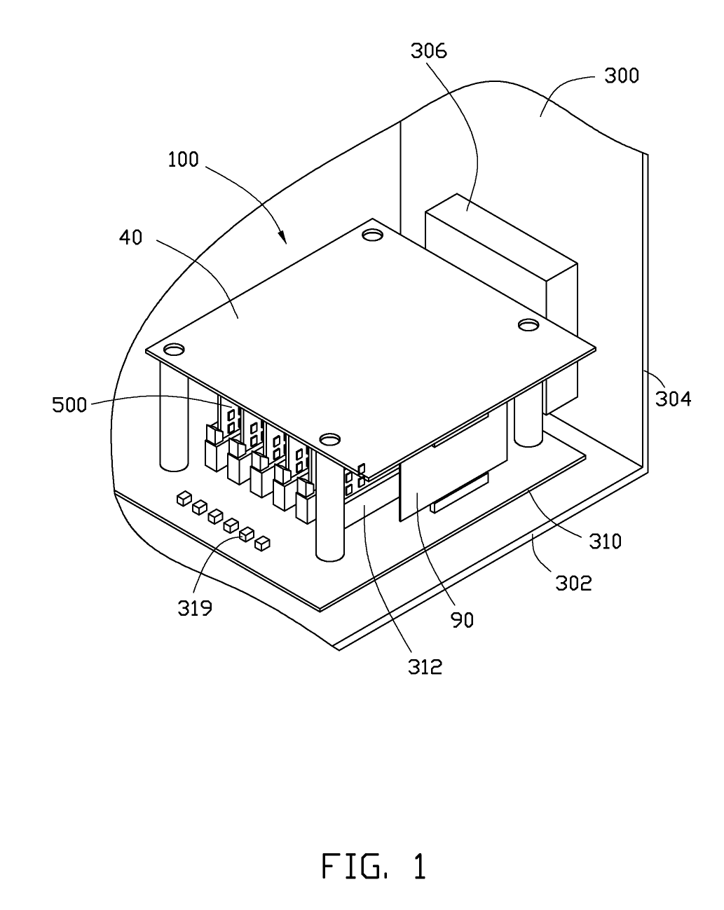

FIG. 1 shows an exemplary embodiment of an electronic device. The electronic device includes a chassis 300, a first printed circuit board (PCB) 310 installed in the chassis 300, and a memory assembly 100. In the embodiment, the first PCB 310 is a motherboard.

The chassis 300 includes a bottom wall 302 for installing the first PCB 310, a sidewall 304 extending up from a side of the bottom wall 302, and a fan 306 installed to an inner surface of the sidewall 304.

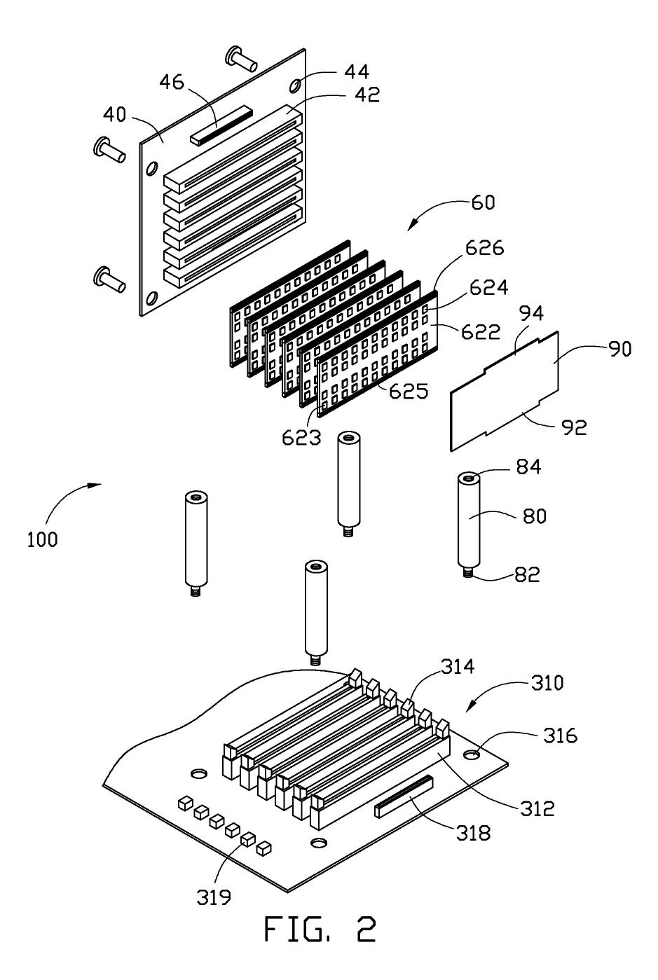

Referring to FIG. 2, a plurality of parallel sockets 312 is formed on a top surface of the first PCB 310, perpendicular to the sidewall 304. Two latching elements 314 are respectively installed to opposite ends of each socket 312. The first PCB 310 defines four screw holes 316, respectively adjacent to four corners of the sockets 312. A connector 318 is mounted on the first PCB 310, adjacent to a side of the sockets 312. A plurality of electronic components 319 is mounted on the PCB 310, away from the fan 306.

The memory assembly 100 includes a second PCB 40, a plurality of memory modules 60, four supporting poles 80, and a third PCB 90.

The second PCB 40 includes a plurality of parallel sockets 42 mounted on a bottom surface of the second PCB 40. The second PCB 40 defines four screw holes 44, respectively adjacent to four corners of the sockets 42. A connector 46 is mounted on the bottom surface of the second PCB 40, adjacent to a side of the sockets 42.

Each of the memory modules 60 includes a rectangular PCB 622, a first edge connector 625 formed on a bottom side of the PCB 622, a second edge connector 626 formed on a top side of the PCB 622. In addition, a plurality of first chips 623 mounted on a lower portion of the PCB 622 and electrically connected to the first edge connector 625, and a plurality of second chips 624 mounted on an upper portion of the PCB 622 and electrically connected to the second edge connector 626. In the embodiment, the first chips 623 and the first edge connector 625 together function as a first memory, and the second chips 624 and the second edge connector 626 together function as a second memory. Thus, each memory module 60 is a dual in-line memory module (DIMM) card, which is equivalent to a combination of two traditional memory modules in capacity.

A threaded pole 82 extends down from a bottom end of each supporting pole 80. A top end of the supporting pole 80 axially defines a screw hole 84.

The third PCB 90 is rectangular, and includes a first edge connector 92 formed on a bottom side of the third PCB 90, and a second edge connector 94 formed on a top side of the third PCB 90 opposite to the first edge connector 92.

In assembly, the first edge connector 625 of each of the memory modules 60 is inserted into the corresponding socket 312 of the first PCB 310. The latching elements 314 latch opposite ends of the corresponding memory modules 60. The threaded poles 82 of the supporting poles 80 are respectively screwed into the screw holes 316 of the first PCB 310. The first edge connector 92 of the third PCB 90 is connected to the connector 318 of the first PCB 310. The sockets 42 of the second PCB 40 are respectively aligned with the second edge connectors 626 of the memory modules 60, and the connector 46 of the second PCB 40 is aligned with the second edge connector 94 of the third PCB 90. The second PCB 40 is pressed down, to allow the second edge connectors 626 of the memory modules 60 to be inserted into the corresponding sockets 42, and allow the second edge connector 94 to be connected to the connector 46. Four screws are respectively extended through the through holes 44 of the second PCB 40, to be screwed into the screw holes 84 of the corresponding supporting poles 80. The second PCB 40 is parallel to the first PCB 310. An air outlet of the fan 306 aligns with an end of the memory assembly 100, away from the electronic components 319 of the first PCB 310. Two adjacent memory modules 60 bind an airflow channel 500 The fan 306 aligns with airflow channels 500 to dissipate heat for the memory assembly 100, and the airflow from the channels 500 can dissipate heat for the electronic components 319.

The third PCB 90 is electrically connected between the first PCB 310 and the second PCB 40. The first chips 623 and the second chips 624 increase the capacity of each memory module 60. Therefore, the memory assembly 100 occupies an area of the first PCB 310 to obtain double capacity, thus, saving a large amount of area of the first PCB 310.

In another embodiment, a plurality of electronic components can be mounted to the second PCB 40.

Even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A memory module comprising:
a printed circuit board (PCB);
a first edge connector formed on a first side of the PCB;
a second edge connector formed on a second side of the PCB;
a plurality of first chips mounted on the PCB and electrically connected to the first edge connector, thereby functioning as a first memory module together with the first edge connector; and
a plurality of second chips mounted on the PCB and electrically connected to the second edge connector, thereby functioning as a second memory module together with the second edge connector.

2. A memory assembly installed to a first printed circuit board (PCB) having a plurality of parallel first sockets, comprising:
a second PCB comprising a plurality of parallel second sockets opposite to the first sockets;
a third PCB electrically connected between the first PCB and the second PCB; and
a plurality of memory modules each comprising a fourth PCB, and a first edge connector and a second edge connectors respectively formed on opposite sides of the fourth PCB, the first edge connector of each memory module inserted into a corresponding one of the first sockets of the first PCB, and the second edge connector of the memory module inserted into a corresponding one of the second sockets of the second PCB.

3. The memory assembly of claim 2, wherein a first connector is mounted on the first PCB, a second connector is mounted on the second PCB, the third PCB comprises a third connector connected to the first connector of the first PCB, and a fourth connector connected to the second connector of the second PCB.

4. The memory assembly of claim 2, wherein a plurality of first and second chips mounted on the fourth PCB, the first chips are connected to the first edge connector to function as a first memory, and the second chips are connected to the second edge connector to function as a second memory.

5. The memory assembly of claim 2, wherein a plurality of supporting poles is mounted between the first PCB and the second PCB.

6. An electronic device, comprising:
a chassis comprising a bottom wall;
a first printed circuit board (PCB) installed on the bottom wall, and comprising a plurality of parallel first sockets;
a second PCB comprising a plurality of parallel second sockets opposite to the first sockets;
a third PCB electrically connected between the first PCB and the second PCB; and
a plurality of memory modules each comprising a fourth PCB, and a first edge connector and a second edge connectors respectively formed on opposite sides of the fourth PCB, the first edge connector of each memory module inserted into a corresponding one of the first sockets of the first PCB, and the second edge connector of the memory module inserted into a corresponding one of the second sockets of the second PCB.

7. The electronic device of claim 6, wherein a first connector is mounted to the first PCB, a second connector is mounted to the second PCB, the third PCB comprises a third connector connected to the first connector of the first PCB, and a fourth connector connected to the second connector of the second PCB.

8. The electronic device of claim 6, wherein a plurality of first and second chips are mounted on the fourth PCB, the first edge connector is connected to the first chips to function as a first memory, and the second edge connector is connected to the second chips to function as a second memory.

9. The electronic device of claim 6, wherein an airflow channel is bounded between two adjacent memories, the chassis further comprises a sidewall extending up from a side of the bottom wall, a fan is installed on the sidewall and faces the airflow channel.

10. The electronic device of claim 6, wherein a plurality of supporting poles is mounted between the first PCB and the second PCB.

11. The electronic device of claim 10, wherein the first PCB defines a plurality of first screw holes, the second PCB defines a plurality of through holes, a threaded pole extends down from a bottom end of each supporting pole to screw into a corresponding first screw hole of the first PCB, and a top end of the supporting pole axially defines a second screw hole, a plurality of screws respectively extends through the through holes, to be screwed into the corresponding second screw holes.
